(19) United States
(12) Patent Application Publication
(10) Pub. No.: US 2026/0026017 A1
(43) Pub. Date: Jan. 22, 2026

(54) SEMICONDUCTOR STRUCTURE AND METHOD FOR CONTROLLING THE SAME

(71) Applicant: Taiwan Semiconductor Manufacturing Company, Ltd., Hsinchu (TW)

(72) Inventors: Hsu Tung Yen, Kaohsiung City (TW); Ling-Sung Wang, Tainan City (TW)

(73) Assignee: Taiwan Semiconductor Manufacturing Company, Ltd., Hsinchu (TW)

(21) Appl. No.: 18/780,404

(22) Filed: Jul. 22, 2024

(51) Int. Cl. H10D 1/20

(52) U.S. Cl. CPC H10D 1/20

(57) ABSTRACT

The embodiments of the disclosure provide a semiconductor structure and a method for controlling a semiconductor structure. The semiconductor structure including a first, second, third, and fourth coil section, and a first and second route switching circuit. The first route switching circuit is coupled to the first, second, third, and fourth coil section. The first route switching circuit in a first mode conducts the first coil section with the second coil section, and the first route switching circuit in a second mode conducts the first coil section with the fourth coil section and conducts the third coil section with the second coil section. The second route switching circuit is coupled to the second and third coil section, wherein the second route switching circuit selectively conducts the fourth coil section with the third coil section.

### BACKGROUND

A variable inductor is an electronic component that allows for the adjustment of its inductance value. Inductance refers to the energy stored in the magnetic field generated by the flow of current through a conductor. Typically, inductors consist of coils of wire, and variations in the current passing through the coil lead to changes in the magnetic field and thus the inductance value.

The primary characteristic of variable inductors is their ability to modify their inductance value through external control mechanisms, making them widely used in various electronic circuits. They find applications in frequency tuning, bandwidth adjustment in filters, resonance circuit tuning, and more.

However, in existing technology, there is no implementation of variable inductance values in an inductor structure through switching coil routes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 shows a schematic diagram of a semiconductor structure according to an embodiment of the disclosure.

FIG. 2A shows a schematic diagram of the first route switching circuit according to FIG. 1 of the disclosure.

FIG. 2B shows a schematic diagram of the second route switching circuit according to FIG. 1 of the disclosure.

FIG. 2C shows a schematic diagram of the third route switching circuit according to FIG. 1 of the disclosure.

FIG. 2D shows a schematic diagram of the fourth route switching circuit according to FIG. 1 of the disclosure.

FIG. 3A shows a signal transmission route corresponding to the first embodiment of the disclosure.

FIG. 3B shows a signal transmission route corresponding to the second embodiment of the disclosure.

FIG. 3C shows a signal transmission route corresponding to the third embodiment of the disclosure.

FIG. 3D shows a signal transmission route corresponding to the fourth embodiment of the disclosure.

FIG. 3E shows a signal transmission route corresponding to the fifth embodiment of the disclosure.

FIG. 4 shows a schematic diagram of Route 1 to Route 5 according to FIG. 2A to FIG. 3E of the disclosure.

FIG. 5 shows a schematic diagram of the semiconductor structure according to another embodiment of the disclosure.

FIG. 6A shows a transistor structure according to an embodiment of the disclosure.

FIG. 6B shows another transistor structure according to an embodiment of the disclosure.

FIG. 7 shows a flow chart of the method for controlling a semiconductor structure according to an embodiment of the disclosure.

### DESCRIPTION OF THE EMBODIMENTS

The following disclosure provides many different embodiments, or examples, for implementing different features of the present disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

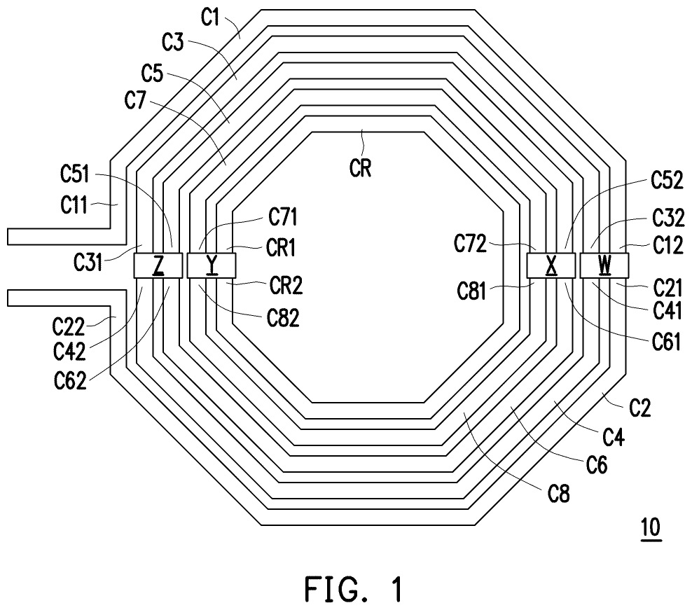

FIG. 1 shows a schematic diagram of a semiconductor structure according to an embodiment of the disclosure.

In the embodiments of the disclosure, the semiconductor structure 10 may be any structure that provides a variable electronic characteristic (e.g., voltage, current, resistance, inductance, capacitance, etc.). For example, the semiconductor structure 10 may be a variable inductor, but the disclosure is not limited thereto.

In FIG. 1, the semiconductor structure 10 includes a first coil section C1, a second coil section C2, a third coil section C3, a fourth coil section C4, a fifth coil section C5, a sixth coil section C6, a seventh coil section C7, an eighth coil section C8, a reference coil section CR, a first route switching circuit W, a second route switching circuit Z, a third route switching circuit X, and a fourth route switching circuit Y.

The first route switching circuit W is coupled to the first coil section C1, the second coil section C2, the third coil section C3, and the fourth coil section C4. The second route switching circuit Z is coupled to the second coil section C2 and the third coil section C3, the fifth coil section C5, and the sixth coil section C6.

The third route switching circuit X is coupled to the fifth coil section C5, the sixth coil section C6, the seventh coil section C7, and the eighth coil section C8. The fourth route switching circuit Y is coupled to the seventh coil section C7, the eighth coil section C8, and the reference coil section CR.

In the embodiments of the disclosure, each of the first coil section C1, the second coil section C2, the third coil section C3, the fourth coil section C4, the fifth coil section C5, the sixth coil section C6, the seventh coil section C7, the eighth coil section C8, and the reference coil section CR has a first end and a second end.

In one embodiment, the first route switching circuit W is coupled to the second end C12 of the first coil section C1, the first end C21 of the second coil section C2, the second end C32 of the third coil section C3, and the first end C41 of the fourth coil section C4.

In one embodiment, the second route switching circuit Z is coupled to the second end C42 of the fourth coil section C4, the first end C31 of the third coil section C3, the first end C51 of the fifth coil section C5 and the second end C62 of the sixth coil section C6.

In one embodiment, the third route switching circuit X is coupled to the second end C52 of the fifth coil section C5, the first end C61 of the sixth coil section C6, the first end C81 of the eighth coil section C8 and the second end C72 of the seventh coil section C7.

In one embodiment, the fourth route switching circuit Y is coupled to the second end C82 of the eighth coil section C8, the first end C71 of the seventh coil section C7, the first end CR1 of the reference coil section CR, and the second end CR2 of the reference coil section CR.

In some embodiments, the coil width of each of the first coil section C1, the second coil section C2, the third coil section C3, the fourth coil section C4, the fifth coil section C5, the sixth coil section C6, the seventh coil section C7, the eighth coil section C8, and the reference coil section CR may range between 0.9 um to 1.8 um.

In some embodiments, the spacing between adjacent coil sections (e.g., the spacing between the first coil section C1 and the third coil section C3, and the spacing between the second coil section C2 and the fourth coil section C4, etc.) may range between 0.9 um to 1.8 um.

In some embodiments, the length of the first coil section C1 and/or the length of the second coil section C2 may range between 100 um to 200 um (C1/C2 each). The length of the third coil section C3 and/or the length of the fourth coil section C4 may range between 85 um to 170 um (C3/C4 each). The length of the fifth coil section C5 and/or the length of the sixth coil section C6 may range between 72 um to 144 um (C5/C6 each). The length of the seventh coil section C7 and/or the length of the eighth coil section C8 may range between 62 um to 124 um (C7/C8 each). The length of the reference coil section CR may range between 104 um to 208 um.

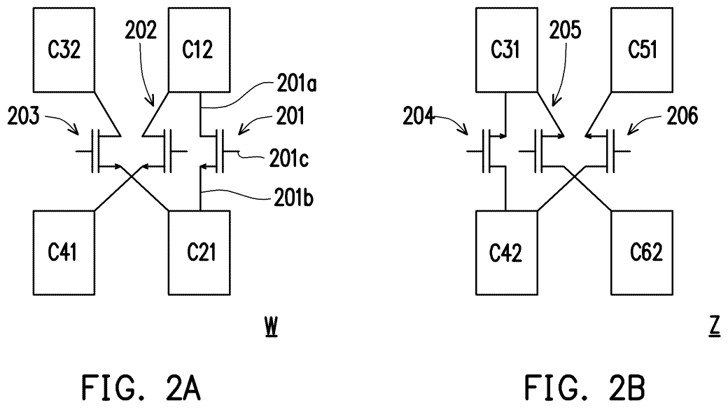

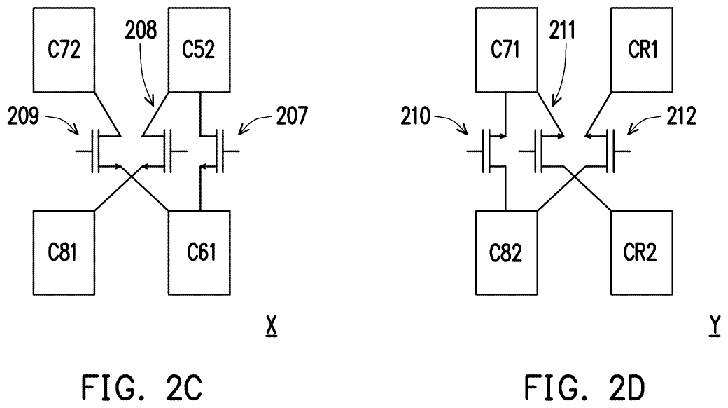

See FIG. 2A, which shows a schematic diagram of the first route switching circuit W according to FIG. 1 of the disclosure. In FIG. 2A, the first route switching circuit W includes a first switch 201, a second switch 202, and a third switch 203.

The first switch 201 has a first terminal and a second terminal, wherein the first terminal of the first switch 201 is coupled to the second end C12 of the first coil section C1, and the second terminal of the first switch 201 is coupled to the first end C21 of the second coil section C2. The second switch 202 has a first terminal and a second terminal, wherein the first terminal of the second switch 202 is coupled to the second end C12 of the first coil section C1, and the second terminal of the second switch 202 is coupled to the first end C41 of the fourth coil section C4. The third switch 203 has a first terminal and a second terminal, wherein the first terminal of the third switch 203 is coupled to the second end C32 of the third coil section C3, and the second terminal of the third switch 203 is coupled to the first end C21 of the second coil section C2.

In the embodiments of the disclosure, each of the mentioned switch can be implemented as a corresponding p-channel metal-oxide semiconductor (pMOS) transistor. For example, the first switch 201 can be implemented as a pMOS transistor as shown in FIG. 2A. In this case, the associated first terminal 201a and second terminal 201b may be, for example, the drain and source of the first switch 201. In addition, the first switch 201 can be turned on (e.g., conducting) or off (e.g., disconnecting) in response to the control signal fed into the control terminal 201c (e.g., the gate) of the first switch 201, but the disclosure is not limited thereto. Similar operating principle can be applied to other switches (e.g., the switches in FIG. 2A to FIG. 2D) mentioned in the disclosure.

In some embodiments, the width of the discussed transistor in the disclosure may range between 10 um to 40 um. In some embodiments, the length of the discussed transistor in the disclosure may be 2.4 um, but the disclosure is not limited thereto.

In transistor design, the length and width refer to the dimensions of the transistor channel of the considered transistor. Specifically, the length of the transistor is the distance between the source and drain along the direction of current flow, and the width of the transistor is the lateral dimension of the channel, perpendicular to the direction of current flow.

In other embodiments, each of the mentioned switch can be alternatively implemented as a corresponding n-channel MOS (nMOS) and/or other kinds of switching structures, and the associated structure of the corresponding route switching circuit can be accordingly adapted, but the disclosure is not limited thereto.

See FIG. 2B, which shows a schematic diagram of the second route switching circuit Z according to FIG. 1 of the disclosure. In FIG. 2B, the second route switching circuit Z includes a fourth switch 204, a fifth switch 205, and a sixth switch 206. The fourth switch 204 has a first terminal and a second terminal, wherein the first terminal of the fourth switch 204 is coupled to the second end C42 of the fourth coil section C4, and the second terminal of the fourth switch 204 is coupled to the first end C31 of the third coil section C3. The fifth switch 205 has a first terminal and a second terminal, wherein the first terminal of the fifth switch 205 is coupled to the second end C62 of the sixth coil section C6, and the second terminal of the fifth switch 205 is coupled to the first end C31 of the third coil section C3. The sixth switch 206 has a first terminal and a second terminal, wherein the first terminal of the sixth switch 206 is coupled to the second end C42 of the fourth coil section C4, and the second terminal of the sixth switch 206 is coupled to the first end C51 of the fifth coil section C5.

See FIG. 2C, which shows a schematic diagram of the third route switching circuit X according to FIG. 1 of the disclosure. In FIG. 2C, the third route switching circuit X includes a seventh switch 207, an eighth switch 208, and a ninth switch 209. The seventh switch 207 has a first terminal and a second terminal, wherein the first terminal of the seventh switch 207 is coupled to the second end C52 of the fifth coil section C5, and the second terminal of the seventh switch 207 is coupled to the first end C61 of the sixth coil section C6. The eighth switch 208 has a first terminal and a second terminal, wherein the first terminal of the eighth switch 208 is coupled to the second end C72 of the seventh coil section C7, and the second terminal of the eighth switch 208 is coupled to the first end C61 of the sixth coil section C6. The ninth switch 209 has a first terminal and a second terminal, wherein the first terminal of the ninth switch 209 is coupled to the second end C52 of the fifth coil section C5, and the second terminal of the ninth switch 209 is coupled to the first end C81 of the eighth coil section C8.

See FIG. 2D, which shows a schematic diagram of the fourth route switching circuit Y according to FIG. 1 of the disclosure. In FIG. 2D, the fourth route switching circuit Y includes a tenth switch 210, an eleventh switch 211, and a twelfth switch 212. The tenth switch 210 has a first terminal and a second terminal, wherein the first terminal of the tenth switch 210 is coupled to the second end C82 of the eighth coil section C8, and the second terminal of the tenth switch 210 is coupled to the first end C71 of the seventh coil section C7. The eleventh switch 211 has a first terminal and a second terminal, wherein the first terminal of the eleventh switch 211 is coupled to the second end CR2 of the reference coil section CR, and the second terminal of the eleventh switch 211 is coupled to the first end C71 of the seventh coil section C7. The twelfth switch 212 has a first terminal and a second terminal, wherein the first terminal of the twelfth switch 212 is coupled to the second end CR2 of the reference coil section CR, and the second terminal of the twelfth switch 212 is coupled to the first end C81 of the eighth coil section C8.

As mentioned in the above each of the switch in FIG. 2A to FIG. 2D can be implemented as a corresponding nMOS transistor, pMOS transistor and/or other kinds of switching structures, and the associated structure of the corresponding route switching circuit can be accordingly adapted, but the disclosure is not limited thereto.

In the embodiments of the disclosure, each of the first route switching circuit W, the second route switching circuit Z, the third route switching circuit X, and the fourth route switching circuit Y operates in a first mode, a second mode or a disconnecting mode.

In the embodiments of the disclosure, the first route switching circuit W in the first mode conducts the first coil section C1 with the second coil section C2, and the first route switching circuit W in the second mode conducts the first coil section C1 with the fourth coil section C4 and conducts the third coil section C3 with the second coil section C2. More specifically, the first route switching circuit W in the first mode conducts the second end C12 of the first coil section C1 with the first end C21 of the second coil section C2, and the first route switching circuit W in the second mode conducts the second end C12 of the first coil section C1 with the first end C41 of the fourth coil section C4 and conducts the second end C32 of the third coil section C3 with the first end C21 of the second coil section C2.

From another perspective, the first route switching circuit W in the first mode can be understood as corresponding to a scenario where the first switch 201 is on while the second switch 202 and the third switch 203 are off. In addition, the first route switching circuit W in the second mode can be understood as corresponding to a scenario where the first switch 201 is off while the second switch 202 and the third switch 203 are on.

In one embodiment, the second route switching circuit Z selectively conducts the fourth coil section C4 with the third coil section C3. More specifically, the second route switching circuit Z selectively conducts the second end C42 of the fourth coil section C4 with the first end C31 of the third coil section C3. For example, the second route switching circuit Z in the first mode conducts the fourth coil section C4 with the third coil section C3 by conducting the second end C42 of the fourth coil section C4 with the first end C31 of the third coil section C3. In addition, the second route switching circuit Z in the disconnecting mode disconnects the fourth coil section C4 with the third coil section C3 by disconnecting the second end C42 of the fourth coil section C4 with the first end C31 of the third coil section C3.

From another perspective, the second route switching circuit Z in the first mode can be understood as corresponding to a scenario where the fourth switch 204 is on while the fifth switch 205 and the sixth switch 206 are off. In addition, the second route switching circuit Z in the disconnecting mode can be understood as corresponding to a scenario where the fourth switch 204, the fifth switch 205 and the sixth switch 206 are off, but the disclosure is not limited thereto.

In a first embodiment, the semiconductor structure 10 provides a first inductance in a case where the first route switching circuit W operates in the first mode.

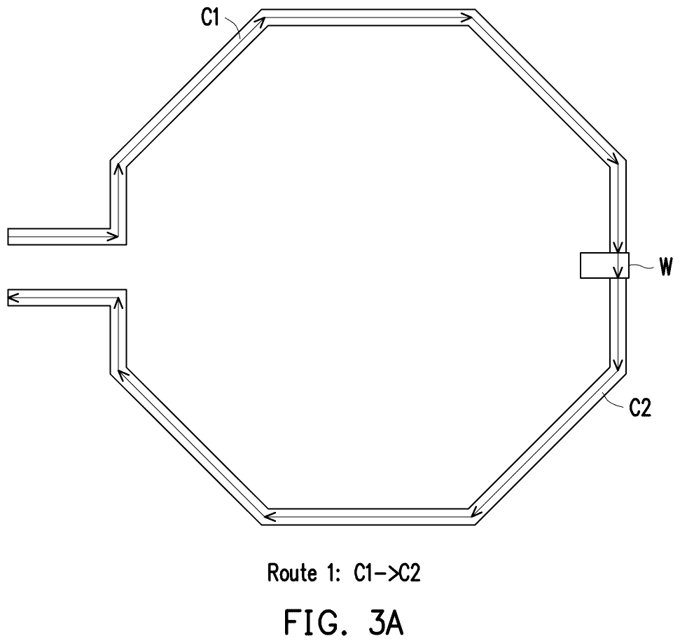

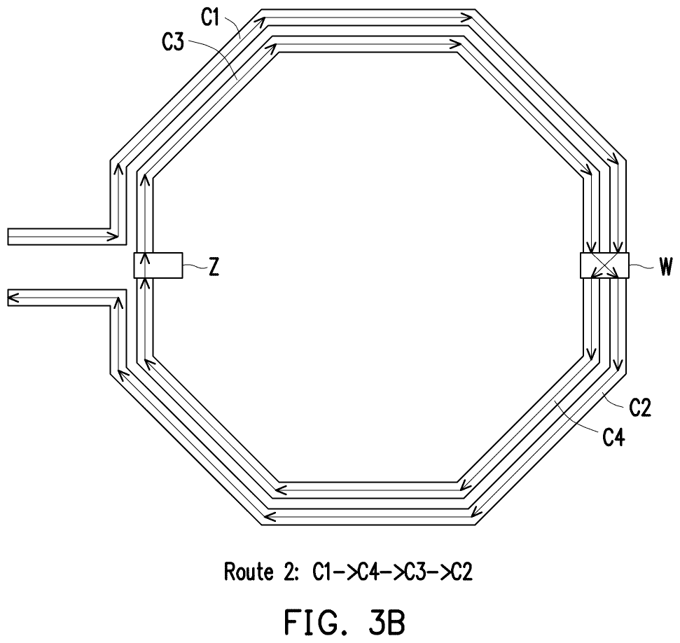

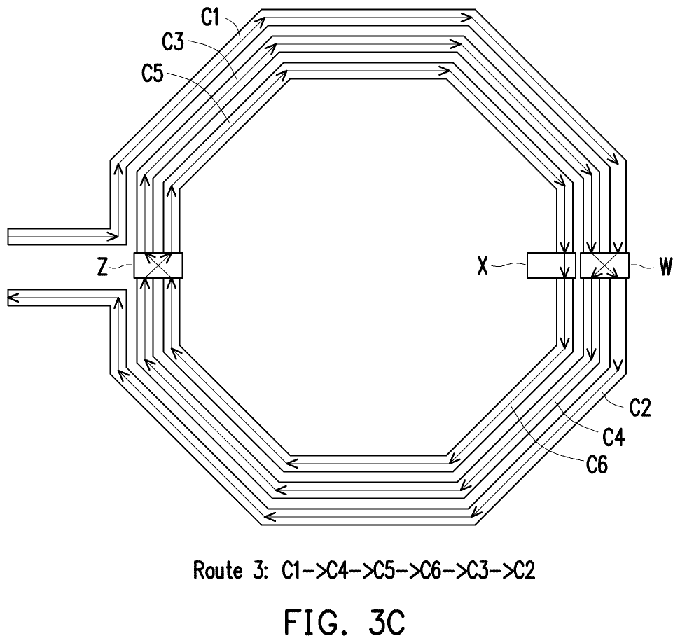

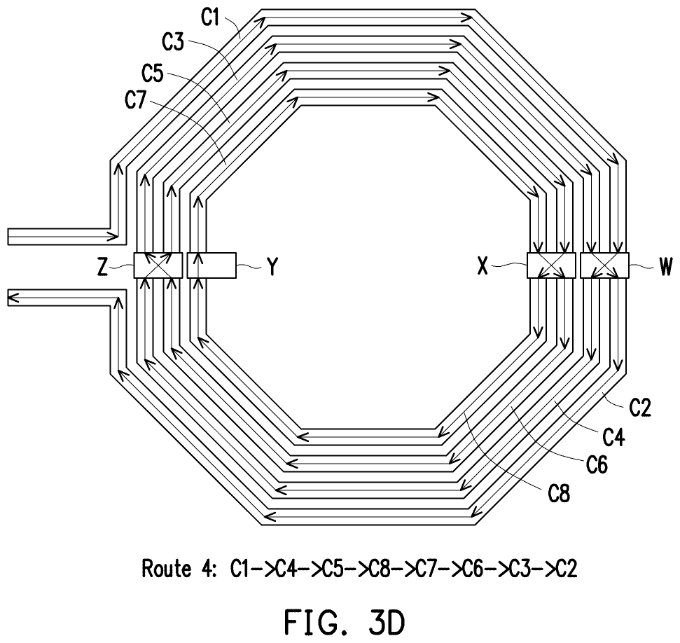

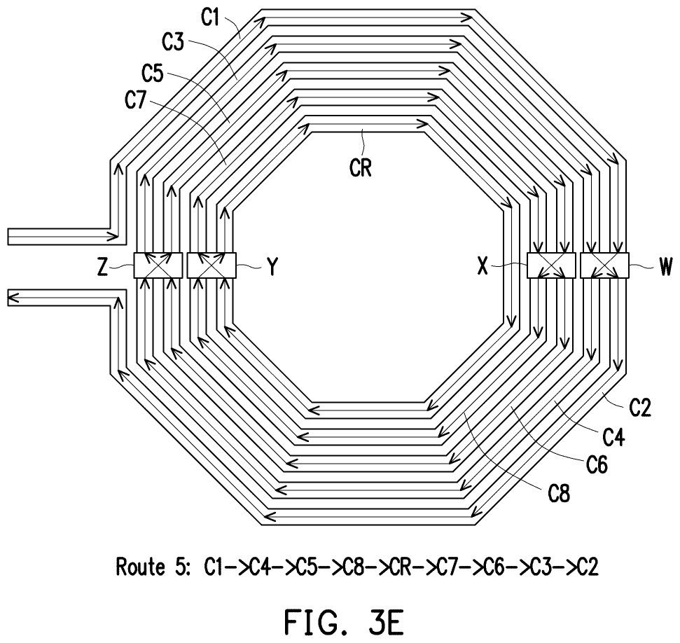

See FIG. 3A, which shows a signal transmission route corresponding to the first embodiment of the disclosure. In FIG. 3A, the first route switching circuit W operates in the first mode, such that the first route switching circuit W conducts the second end C12 of the first coil section C1 with the first end C21 of the second coil section C2.

In the embodiment, the first coil section C1 provides an input terminal (e.g., the first end C11 of the first coil section C1) of the semiconductor structure 10, and the second coil section C2 provides an output terminal (e.g., the second end C22 of the second coil section C2) of the semiconductor structure 10. More specifically, the first end C11 of the first coil section C1 can be used as the input terminal of the semiconductor structure 10, wherein the first end C11 can be used to receive an input signal. In addition, the second end C22 of the second coil section C2 can be used as the output terminal of the semiconductor structure 10. In the embodiments of the disclosure, the input signal may be a current signal whose current value ranges between 0.01A to 2 A, but the disclosure is not limited thereto.

In this case, when the semiconductor structure 10 receives an input signal via the input terminal provided by the first coil section C1, this input signal would sequentially pass the first coil section C1, the first route switching circuit (in particular, the first switch 201), and the second coil section C2, and this signal transmission route may be referred to as Route 1 in FIG. 3A.

In FIG. 3A, the corresponding inductance by the semiconductor structure 10 can be referred to as the first inductance, but the disclosure is not limited thereto.

In a second embodiment, the semiconductor structure 10 provides a second inductance in a case where the first route switching circuit W operates in the second mode and the second route switching circuit Z conducts the fourth coil section C4 with the third coil section C3 (e.g., the second route switching circuit Z operates in the first mode).

See FIG. 3B, which shows a signal transmission route corresponding to the second embodiment of the disclosure. In FIG. 3B, the first route switching circuit W operates in the second mode and the second route switching circuit Z operates in the first mode. In this case, when the semiconductor structure 10 receives an input signal via the input terminal provided by the first coil section C1, this input signal would sequentially pass the first coil section C1, the first route switching circuit W (in particular, the second switch 202), the fourth coil section C4, the second route switching circuit Z (in particular, the fourth switch 204), the third coil section C3, the first route switching circuit W (in particular, the third switch 203), and the second coil section C2, and this signal transmission route may be referred to as Route 2 in FIG. 3B.

In FIG. 3B, the corresponding inductance by the semiconductor structure 10 can be referred to as the second inductance, but the disclosure is not limited thereto. In addition, since Route 2 is longer than Route 1 in FIG. 3A, the second inductance would be higher than the first inductance.

From another perspective, since the length of the signal transmission route of the input signal can be adjusted by managing the operating modes of the first route switching circuit W and/or the second route switching circuit Z, the inductance provided by the semiconductor structure 10 can be varied. Accordingly, the embodiments of the disclosure provide a novel way for implementing a semiconductor structure 10.

In one embodiment, the second route switching circuit Z in the second mode conducts the fourth coil section C4 with the fifth coil section C5 and conducts the sixth coil section C6 with the third coil section C3. From another perspective, the second route switching circuit Z in the second mode can be understood as corresponding to a scenario where the fourth switch 204 is off while the fifth switch 205 and the sixth switch 206 are on.

In one embodiment, the third route switching circuit X selectively conducts the fifth coil section C5 with the sixth coil section C6. More specifically, the third route switching circuit X selectively conducts the second end C52 of the fifth coil section C5 with the first end C61 of the sixth coil section C6. For example, the third route switching circuit X in the first mode conducts the fifth coil section C5 with the sixth coil section C6 by conducting the second end C52 of the fifth coil section C5 with the first end C61 of the sixth coil section C6. In addition, the third route switching circuit X in the disconnecting mode disconnects the fifth coil section C5 with the sixth coil section C6 by disconnecting the second end C52 of the fifth coil section C5 with the first end C61 of the sixth coil section C6.

From another perspective, the third route switching circuit X in the first mode can be understood as corresponding to a scenario where the seventh switch 207 is on while the eighth switch 208 and the ninth switch 209 are off. In addition, the third route switching circuit X in the disconnecting mode can be understood as corresponding to a scenario where the seventh switch 207, the eighth switch 208 and the ninth switch 209 are off, but the disclosure is not limited thereto.

In a third embodiment, the semiconductor structure 10 provides a third inductance in a case where the first route switching circuit W operates in the second mode, the second route switching circuit Z operates in the second mode, and the third route switching circuit X conducts the fifth coil section C5 with the sixth coil section C6 (e.g., the third route switching circuit X operates in the first mode).

See FIG. 3C, which shows a signal transmission route corresponding to the third embodiment of the disclosure. In FIG. 3C, the first route switching circuit W operates in the second mode, the second route switching circuit Z operates in the second mode, and the third route switching circuit X operates in the first mode. In this case, when the semiconductor structure 10 receives an input signal via the input terminal provided by the first coil section C1, this input signal would sequentially pass the first coil section C1, the first route switching circuit W (in particular, the second switch 202), the fourth coil section C4, the second route switching circuit Z (in particular, the sixth switch 206), the fifth coil section C5, the third route switching circuit X (in particular, the seventh switch 207), the sixth coil section C6, the second route switching circuit Z (in particular, the fifth switch 205), the third coil section C3, the first route switching circuit W (in particular, the third switch 203), and the second coil section C2, and this signal transmission route may be referred to as Route 3 in FIG. 3C.

In FIG. 3C, the corresponding inductance by the semiconductor structure 10 can be referred to as the third inductance, but the disclosure is not limited thereto. In addition, since Route 3 is longer than Route 2 in FIG. 3B, the third inductance would be higher than the second inductance.

In one embodiment, the third route switching circuit X in the second mode conducts the fifth coil section C5 with the eighth coil section C8 and conducts the seventh coil section C7 with the sixth coil section C6. From another perspective, the third route switching circuit X in the second mode can be understood as corresponding to a scenario where the seventh switch 207 is off while the eighth switch 208 and the ninth switch 209 are on.

In one embodiment, the fourth route switching circuit Y selectively conducts the seventh coil section C7 with the eighth coil section C8. More specifically, the fourth route switching circuit Y selectively conducts the second end C82 of the eighth coil section C8 with the first end C71 of the seventh coil section C7. For example, the fourth route switching circuit Y in the first mode conducts the seventh coil section C7 with the eighth coil section C8 by conducting the second end C82 of the eighth coil section C8 with the first end C71 of the seventh coil section C7. In addition, the fourth route switching circuit Y in the disconnecting mode disconnects the seventh coil section C7 with the eighth coil section C8 by disconnecting the second end C82 of the eighth coil section C8 with the first end C71 of the seventh coil section C7.

From another perspective, the fourth route switching circuit Y in the first mode can be understood as corresponding to a scenario where the tenth switch 210 is on while the eleventh switch 211 and the twelfth switch 212 are off. In addition, the fourth route switching circuit Y in the disconnecting mode can be understood as corresponding to a scenario where the tenth switch 210, the eleventh switch 211, and the twelfth switch 212 are off, but the disclosure is not limited thereto.

In a fourth embodiment, the semiconductor structure 10 provides a fourth inductance in a case where the first route switching circuit W operates in the second mode, the second route switching circuit Z operates in the second mode, the third route switching circuit X operates in the second mode, and the fourth route switching circuit Y conducts the eighth coil section C8 with the seventh coil section C7 (e.g., the fourth route switching circuit Y operates in the first mode).

See FIG. 3D, which shows a signal transmission route corresponding to the fourth embodiment of the disclosure. In FIG. 3D, the first route switching circuit W operates in the second mode, the second route switching circuit Z operates in the second mode, the third route switching circuit X operates in the second mode, and the fourth route switching circuit Y operates in the first mode. In this case, when the semiconductor structure 10 receives an input signal via the input terminal provided by the first coil section C1, this input signal would sequentially pass the first coil section C1, the first route switching circuit W (in particular, the second switch 202), the fourth coil section C4, the second route switching circuit Z (in particular, the sixth switch 206), the fifth coil section C5, the third route switching circuit X (in particular, the eighth switch 208), the eighth coil section C8, the fourth route switching circuit Y (in particular, the tenth switch 210), the seventh coil section C7, the third route switching circuit X (in particular, the ninth switch 209), the sixth coil section C6, the second route switching circuit Z (in particular, the fifth switch 205), the third coil section C3, the first route switching circuit W (in particular, the third switch 203), and the second coil section C2, and this signal transmission route may be referred to as Route 4 in FIG. 3D.

In FIG. 3D, the corresponding inductance by the semiconductor structure 10 can be referred to as the fourth inductance, but the disclosure is not limited thereto. In addition, since Route 4 is longer than Route 3 in FIG. 3C, the fourth inductance would be higher than the third inductance.

In one embodiment, the fourth route switching circuit Y in the second mode conducts the eighth coil section C8 with the reference coil section CR and conducts the reference coil section CR with the seventh coil section C7. From another perspective, the fourth route switching circuit Y in the second mode can be understood as corresponding to a scenario where the tenth switch 210 is off while the eleventh switch 211 and the twelfth switch 212 are on.

In a fifth embodiment, the semiconductor structure 10 provides a fifth inductance in a case where the first route switching circuit W operates in the second mode, the second route switching circuit Z operates in the second mode, the third route switching circuit X operates in the second mode, the fourth route switching circuit Y operates in the second mode.

See FIG. 3E, which shows a signal transmission route corresponding to the fifth embodiment of the disclosure. In FIG. 3E, the first route switching circuit W operates in the second mode, the second route switching circuit Z operates in the second mode, the third route switching circuit X operates in the second mode, and the fourth route switching circuit Y operates in the second mode. In this case, when the semiconductor structure 10 receives an input signal via the input terminal provided by the first coil section C1, this input signal would sequentially pass the first coil section C1, the first route switching circuit W (in particular, the second switch 202), the fourth coil section C4, the second route switching circuit Z (in particular, the sixth switch 206), the fifth coil section C5, the third route switching circuit X (in particular, the eighth switch 208), the eighth coil section C8, the fourth route switching circuit Y (in particular, the twelfth switch 212), the reference coil section CR, the fourth route switching circuit Y (in particular, the eleventh switch 211), the seventh coil section C7, the third route switching circuit X (in particular, the ninth switch 209), the sixth coil section C6, the second route switching circuit Z (in particular, the fifth switch 205), the third coil section C3, the first route switching circuit W (in particular, the third switch 203), and the second coil section C2, and this signal transmission route may be referred to as Route 5 in FIG. 3E.

In FIG. 3E, the corresponding inductance by the semiconductor structure 10 can be referred to as the fifth inductance, but the disclosure is not limited thereto. In addition, since Route 5 is longer than Route 4 in FIG. 3D, the fifth inductance would be higher than the fourth inductance.

In the embodiment, the range of the first inductance may range between 20 nH to 30 nH. The range of the second inductance may range between 40 nH to 60 nH. The range of the third inductance may range between 60 nH to 90 nH. The range of the fourth inductance may range between 80 nH to 120 nH. The range of the fifth inductance may range between 100 nH to 150 nH.

In one embodiment, the ratio between the first inductance (e.g., a minimum inductance provided by the semiconductor structure 10) and the fifth inductance (e.g., a maximum inductance provided by the semiconductor structure 10) may range between 3.3× to 7.5×, but the disclosure is not limited thereto.

From another perspective, since the length of the signal transmission route of the input signal can be adjusted by managing the operating modes of the first route switching circuit W to the fourth route switching circuit Y, the inductance provided by the semiconductor structure 10 can be varied. Accordingly, the embodiments of the disclosure provide a novel way for implementing a semiconductor structure 10.

In some embodiments, the combinations of the modes of the first route switching circuit W to the fourth route switching circuit Y corresponding to Route 1 to Route 5 may be exemplarily summarized as the following Table 1.

TABLE 1

| | Route 1 | Route 2 | Route 3 | Route 4 | Route 5 |
|---|---|---|---|---|---|
| W | First | Second | Second | Second | Second |
| | mode | mode | mode | mode | mode |
| Z | Disconnecting | First | Second | Second | Second |
| | mode | mode | mode | mode | mode |
| X | Disconnecting | Disconnecting | First | Second | Second |
| | mode | mode | mode | mode | mode |
| Y | Disconnecting | Disconnecting | Disconnecting | First | Second |
| | mode | mode | mode | mode | mode |

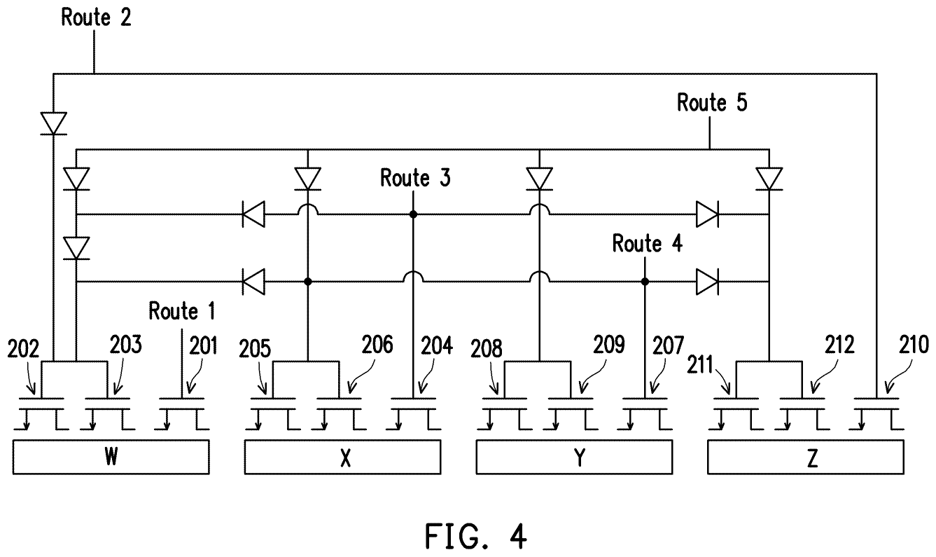

See FIG. 4, which shows a schematic diagram of Route 1 to Route 5 according to FIG. 2A to FIG. 3E of the disclosure. In FIG. 4, the detailed signal transmission routes corresponding to Route 1 to Route 5 may be referred to the descriptions associated with the first embodiment to the fifth embodiment, which would not be repeated herein.

In some embodiments, the semiconductor structure 10 may be modified to include additional coil sections and route switching circuits, and these additional coil sections and route switching circuits may be added by using the similar structure of the existing elements in the semiconductor structure 10, but the disclosure is not limited thereto.

In some embodiments, although the coil sections in the semiconductor structure 10 is illustrated in a polygon-like approach, the coil sections may be designed to have other appearances, such as arc, but the disclosure is not limited thereto.

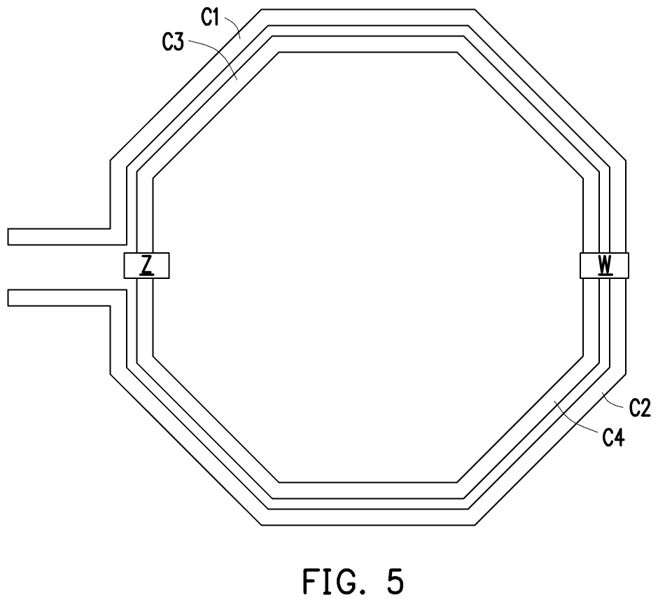

See FIG. 5, which shows a schematic diagram of the semiconductor structure according to another embodiment of the disclosure.

In FIG. 5, the semiconductor structure 50 includes a first coil section C1, a second coil section C2, a third coil section C3, a fourth coil section C4, a first route switching circuit W, and a second route switching circuit Z.

The first coil section C1 provides an input terminal of the semiconductor structure. The second coil section C2 provides an output terminal of the semiconductor structure. The first route switching circuit W is coupled to the first coil section C1, the second coil section C2, the third coil section C3, and the fourth coil section C4, wherein the first route switching circuit W operates in a first mode or a second mode. The first route switching circuit W in the first mode conducts the first coil section C1 with the second coil section C2, and the first route switching circuit W in the second mode conducts the first coil section C1 with the fourth coil section C4 and conducts the third coil section C3 with the second coil section C2. The second route switching circuit Z is coupled to the second coil section C2 and the third coil section C3, wherein the second route switching circuit Z selectively conducts the fourth coil section C4 with the third coil section C3.

In the embodiment, the semiconductor structure 50 may be understood as a simplified version of the semiconductor structure 10 in FIG. 1. The semiconductor structure 50 may be used to implement Route 1 in FIG. 3A and Route 2 in FIG. 3B, and the associated details may be referred to the above embodiments, which would not be repeated herein.

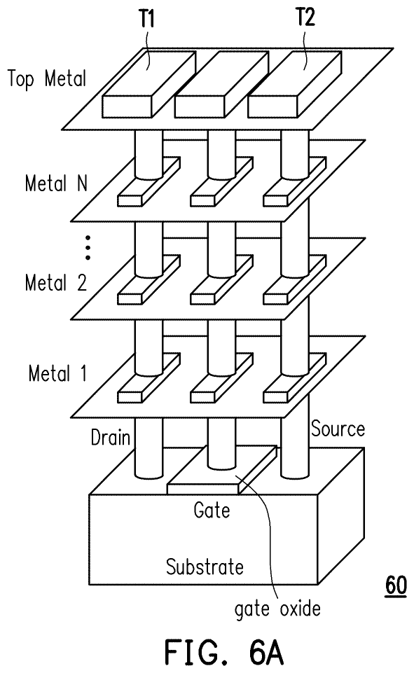

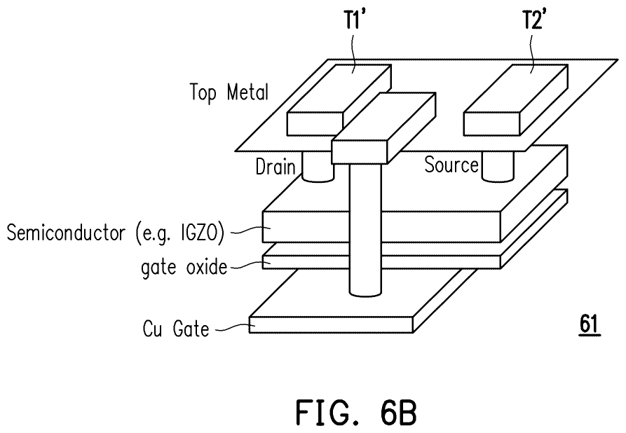

See FIG. 6A, which shows a transistor structure according to an embodiment of the disclosure. In the embodiment, the transistor structure 60 may be used implement each of the switch mentioned in the above.

In FIG. 6A, the transistor structure 60 includes a substrate, N middle metal layers (N is a positive integer larger than 1), a gate oxide, and a top metal layer. In the embodiment, the N middle metal layers may be serially connected between the substrate and the top metal layer. The drain, gate, and source may be disposed on the substrate, and the corresponding first terminal T1 and second terminal T2 may be designed to be on the top metal layer.

See FIG. 6B, which shows another transistor structure according to an embodiment of the disclosure. In the embodiment, the transistor structure 61 may be used implement each of the switch mentioned in the above.

In FIG. 6B, the transistor structure 61 includes a gate layer (e.g., a Cu gate), a gate oxide, a semiconductor layer (e.g., Indium gallium zinc oxide (IGZO)), and a top metal layer. In the embodiment, the drain and source may be disposed on the semiconductor layer, and the corresponding first terminal T1′ and second terminal T2′ may be designed to be on the top metal layer.

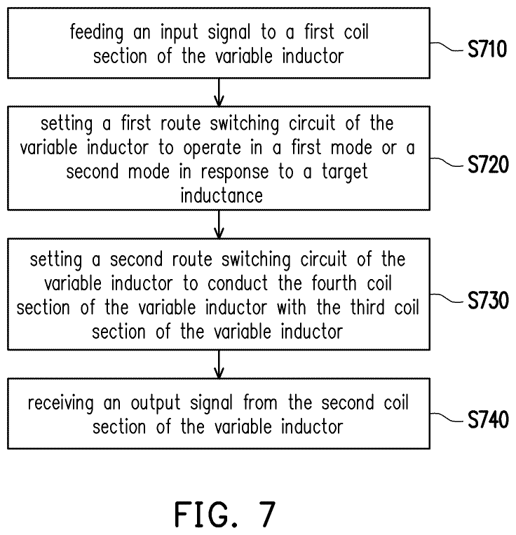

See FIG. 7, which shows a flow chart of the method for controlling a semiconductor structure to provide a variable inductance according to an embodiment of the disclosure. In some embodiments, the method in FIG. 7 may be performed by a control circuit that manages the inductance of the semiconductor structure 50, but the disclosure is not limited thereto.

In step S750, an input signal is fed to a first coil section C1 of the semiconductor structure 50. In step S720, a first route switching circuit W of the semiconductor structure 50 is set to operate in a first mode or a second mode in response to a target inductance, wherein the first route switching circuit W in the first mode conducts the first coil section C1 with a second coil section C2 of the semiconductor structure 50, and the first route switching circuit W in the second mode conducts the first coil section C1 with a fourth coil section C4 of the semiconductor structure 50 and conducts a third coil section C3 of the semiconductor structure 50 with the second coil section C2 of the semiconductor structure 50.

In step S730, a second route switching circuit Z of the semiconductor structure 50 is set to conduct the fourth coil section C4 of the semiconductor structure 50 with the third coil section C3 of the semiconductor structure 50. In step S740, an output signal is received from the second coil section C2 of the semiconductor structure 50.

In one embodiment, if the target inductance in step S720 is, for example, the first inductance, the first route switching circuit W may be set in step S720 to be operating in the first mode, such that the semiconductor structure 50 may provide the signal transmission route as Route 1 in FIG. 3A. In the embodiment, the second route switching circuit Z, the third route switching circuit X, and the fourth route switching circuit Y may be set to operate in the disconnecting mode, but the disclosure is not limited thereto.

In another embodiment, if the target inductance in step S720 is, for example, the second inductance, the first route switching circuit W may be set in step S720 to be operating in the second mode, and the second switching circuit may be set in step S730 to conduct the fourth coil section C4 with the third coil section C3, such that the semiconductor structure 50 may provide the signal transmission route as Route 2 in FIG. 3B. In the embodiment, the third route switching circuit X, and the fourth route switching circuit Y may be set to operate in the disconnecting mode, but the disclosure is not limited thereto.

In some embodiments, the method in FIG. 7 can also be applied to the semiconductor structure 10 in FIG. 1, such that the semiconductor structure 10 can provide the first inductance or the second inductance.

In some embodiments, the method in FIG. 7 can be extended to further control/manage the semiconductor structure 10 to provide the third inductance, the fourth inductance, or the fifth inductance.

In one embodiment, if the target inductance is the third inductance, the first route switching circuit W and the second route switching circuit Z may be set to operate in the corresponding second mode, and the third route switching circuit X may be set to operate in the corresponding first mode. In this case, the semiconductor structure 10 can provide the third inductance by providing the signal transmission route as Route 3 in FIG. 3C. In the embodiment, the fourth route switching circuit Y may be set to operate in the disconnecting mode, but the disclosure is not limited thereto.

In one embodiment, if the target inductance is the fourth inductance, the first route switching circuit W, the second route switching circuit Z, and the third route switching circuit X may be set to operate in the corresponding second mode, and the fourth route switching circuit Y may be set to operate in the corresponding first mode. In this case, the semiconductor structure 10 can provide the fourth inductance by providing the signal transmission route as Route 4 in FIG. 3D.

In one embodiment, if the target inductance is the fifth inductance, the first route switching circuit W, the second route switching circuit Z, the third route switching circuit X, and the fourth route switching circuit Y may be set to operate in the corresponding second mode. In this case, the semiconductor structure 10 can provide the fifth inductance by providing the signal transmission route as Route 5 in FIG. 3E.

In accordance with some embodiments, a semiconductor structure including a first coil section, a second coil section, a third coil section, a fourth coil section, a first route switching circuit, and a second route switching circuit is introduced. The first coil section provides an input terminal of the semiconductor structure. The second coil section provides an output terminal of the semiconductor structure. The first route switching circuit is coupled to the first coil section, the second coil section, the third coil section, and the fourth coil section, wherein the first route switching circuit operates in a first mode or a second mode. The first route switching circuit in the first mode conducts the first coil section with the second coil section, and the first route switching circuit in the second mode conducts the first coil section with the fourth coil section and conducts the third coil section with the second coil section. The second route switching circuit is coupled to the second coil section and the third coil section, wherein the second route switching circuit selectively conducts the fourth coil section with the third coil section.

In accordance with some embodiments, a semiconductor structure including a first coil section, a second coil section, a third coil section, a fourth coil section, a first route switching circuit, and a second route switching circuit is introduced. The first route switching circuit is coupled to the first coil section, the second coil section, the third coil section, and the fourth coil section, wherein the first route switching circuit operates in a first mode or a second mode. The first route switching circuit in the first mode conducts the first coil section with the second coil section, and the first route switching circuit in the second mode conducts the first coil section with the fourth coil section and conducts the third coil section with the second coil section. The second route switching circuit is coupled to the third coil section and the fourth coil section, wherein the second route switching circuit operates in the first mode or a disconnecting mode, wherein the second route switching circuit in the first mode conducts the fourth coil section with the third coil section, and the second route switching circuit in the disconnecting mode disconnects the fourth coil section with the third coil section.

In accordance with some embodiments, a method for controlling a semiconductor structure is introduced. The method includes: feeding an input signal to a first coil section of the semiconductor structure; setting a first route switching circuit of the semiconductor structure to operate in a first mode or a second mode in response to a target inductance, wherein the first route switching circuit in the first mode conducts the first coil section with a second coil section of the semiconductor structure, and the first route switching circuit in the second mode conducts the first coil section with a fourth coil section of the semiconductor structure and conducts a third coil section of the semiconductor structure with the second coil section of the semiconductor structure; setting a second route switching circuit of the semiconductor structure to conduct the fourth coil section of the semiconductor structure with the third coil section of the semiconductor structure; and receiving an output signal from the second coil section of the semiconductor structure.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A semiconductor structure, comprising:
a first coil section, providing an input terminal of the semiconductor structure;
a second coil section, providing an output terminal of the semiconductor structure;
a third coil section;
a fourth coil section;
a first route switching circuit, coupled to the first coil section, the second coil section, the third coil section, and the fourth coil section, wherein the first route switching circuit operates in a first mode or a second mode, wherein the first route switching circuit in the first mode conducts the first coil section with the second coil section, and the first route switching circuit in the second mode conducts the first coil section with the fourth coil section and conducts the third coil section with the second coil section;
a second route switching circuit, coupled to the second coil section and the third coil section, wherein the second route switching circuit selectively conducts the fourth coil section with the third coil section.

2. The semiconductor structure according to claim 1, wherein the semiconductor structure provides a first inductance in a case where the first route switching circuit operates in the first mode;
wherein the semiconductor structure provides a second inductance in a case where the first route switching operates in the second mode and the second route switching circuit conducts the fourth coil section with the third coil section, wherein the second inductance is higher than the first inductance.

3. The semiconductor structure according to claim 1, wherein each of the first coil section, the second coil section, the third coil section, and the fourth coil section has a first end and a second end;
wherein the first route switching circuit is coupled to the second end of the first coil section, the first end of the second coil section, the second end of the third coil section, and the first end of the fourth coil section, wherein the first route switching circuit in the first mode conducts the second end of the first coil section with the first end of the second coil section, and the first route switching circuit in the second mode conducts the second end of the first coil section with the first end of the fourth coil section and conducts the second end of the third coil section with the first end of the second coil section;
wherein the second route switching circuit is coupled to the second end of the fourth coil section and the first end of the third coil section, wherein the second route switching circuit selectively conducts the second end of the fourth coil section with the first end of the third coil section.

4. The semiconductor structure according to claim 3, wherein the first route switching circuit comprises:
a first switch, having a first terminal and a second terminal, wherein the first terminal of the first switch is coupled to the second end of the first coil section, and the second terminal of the first switch is coupled to the first end of the second coil section;
a second switch, having a first terminal and a second terminal, wherein the first terminal of the second switch is coupled to the second end of the first coil section, and the second terminal of the second switch is coupled to the first end of the fourth coil section; and
a third switch, having a first terminal and a second terminal, wherein the first terminal of the third switch is coupled to the second end of the third coil section, and the second terminal of the third switch is coupled to the first end of the second coil section.

5. The semiconductor structure according to claim 1, further comprising:
a fifth coil section, coupled to the second route switching circuit;
a sixth coil section, coupled to the second route switching circuit;
a third route switching circuit, coupled to the fifth coil section and the sixth coil section, wherein the third route switching circuit selectively conducts the fifth coil section with the sixth coil section;
wherein the second route switching circuit operates in the first mode or the second mode, wherein the second route switching circuit in the first mode conducts the fourth coil section with the third coil section, and the second route switching circuit in the second mode conducts the fourth coil section with the fifth coil section and conducts the sixth coil section with the third coil section.

6. The semiconductor structure according to claim 5, wherein each of the fifth coil section and the sixth coil section has a first end and a second end;
wherein the second route switching circuit is coupled to the first end of the fifth coil section and the second end of the sixth coil section;
wherein the third route switching circuit is coupled to the second end of the fifth coil section and the first end of the sixth coil section.

7. The semiconductor structure according to claim 6, wherein the second route switching circuit comprises:
a fourth switch, having a first terminal and a second terminal, wherein the first terminal of the fourth switch is coupled to the second end of the fourth coil section, and the second terminal of the fourth switch is coupled to the first end of the third coil section;
a fifth switch, having a first terminal and a second terminal, wherein the first terminal of the fifth switch is coupled to the second end of the sixth coil section, and the second terminal of the fifth switch is coupled to the first end of the third coil section;
a sixth switch, having a first terminal and a second terminal, wherein the first terminal of the sixth switch is coupled to the second end of the fourth coil section, and the second terminal of the sixth switch is coupled to the first end of the fifth coil section.

8. The semiconductor structure according to claim 5, wherein the semiconductor structure provides a third inductance in a case where the first route switching circuit operates in the second mode, the second route switching circuit operates in the second mode, and the third route switching circuit conducts the fifth coil section with the sixth coil section.

9. The semiconductor structure according to claim 5, further comprising:
a seventh coil section, coupled to the third route switching circuit;
an eighth coil section, coupled to the third route switching circuit;
a fourth route switching circuit, coupled to the seventh coil section and the eighth coil section, wherein the fourth route switching circuit selectively conducts the seventh coil section with the eighth coil section;
wherein the third route switching circuit operates in the first mode or the second mode, wherein the third route switching circuit in the first mode conducts the fifth coil section with the sixth coil section, and the third route switching circuit in the second mode conducts the fifth coil section with the eighth coil section and conducts the seventh coil section with the sixth coil section.

10. The semiconductor structure according to claim 9, wherein each of the seventh coil section and the eighth coil section has a first end and a second end;
wherein the third route switching circuit is coupled to the first end of the eighth coil section and the second end of the seventh coil section;
wherein the fourth route switching circuit is coupled to the second end of the eighth coil section and the first end of the seventh coil section.

11. The semiconductor structure according to claim 10, wherein the third route switching circuit comprises:
a seventh switch, having a first terminal and a second terminal, wherein the first terminal of the seventh switch is coupled to the second end of the fifth coil section, and the second terminal of the seventh switch is coupled to the first end of the sixth coil section;
an eighth switch, having a first terminal and a second terminal, wherein the first terminal of the eighth switch is coupled to the second end of the seventh coil section, and the second terminal of the eighth switch is coupled to the first end of the sixth coil section;
a ninth switch, having a first terminal and a second terminal, wherein the first terminal of the ninth switch is coupled to the second end of the fifth coil section, and the second terminal of the ninth switch is coupled to the first end of the eighth coil section.

12. The semiconductor structure according to claim 9, wherein the semiconductor structure provides a fourth inductance in a case where the first route switching circuit operates in the second mode, the second route switching circuit operates in the second mode, the third route switching circuit operates in the second mode, and the fourth route switching circuit conducts the eighth coil section with the seventh coil section.

13. The semiconductor structure according to claim 9, further comprising:
a reference coil section, coupled to the fourth route switching circuit;
wherein the fourth route switching circuit operates in the first mode or the second mode, wherein the fourth route switching circuit in the first mode conducts the eighth coil section with the seventh coil section, and the fourth route switching circuit in the second mode conducts the eighth coil section with the reference coil section and conducts the reference coil section with the seventh coil section.

14. The semiconductor structure according to claim 13, wherein the reference coil section has a first end and a second end, and the fourth route switching circuit comprises:
a tenth switch, having a first terminal and a second terminal, wherein the first terminal of the tenth switch is coupled to the second end of the eighth coil section, and the second terminal of the tenth switch is coupled to the first end of the seventh coil section;
an eleventh switch, having a first terminal and a second terminal, wherein the first terminal of the eleventh switch is coupled to the second end of the reference coil section, and the second terminal of the eleventh switch is coupled to the first end of the seventh coil section;
a twelfth switch, having a first terminal and a second terminal, wherein the first terminal of the twelfth switch is coupled to the second end of the reference coil section, and the second terminal of the twelfth switch is coupled to the first end of the eighth coil section.

15. The semiconductor structure according to claim 13, wherein the semiconductor structure provides a fifth inductance in a case where each of the first route switching circuit, the second route switching circuit, the third route switching circuit, and the fourth route switching circuit operates in the second mode.

16. A semiconductor structure, comprising:
a first coil section, providing an input terminal of the semiconductor structure;
a second coil section, providing an output terminal of the semiconductor structure;
a third coil section;
a fourth coil section;
a first route switching circuit, coupled to the first coil section, the second coil section, the third coil section, and the fourth coil section, wherein the first route switching circuit operates in a first mode or a second mode, wherein the first route switching circuit in the first mode conducts the first coil section with the second coil section, and the first route switching circuit in the second mode conducts the first coil section with the fourth coil section and conducts the third coil section with the second coil section;
a second route switching circuit, coupled to the third coil section and the fourth coil section, wherein the second route switching circuit operates in the first mode or a disconnecting mode, wherein the second route switching circuit in the first mode conducts the fourth coil section with the third coil section, and the second route switching circuit in the disconnecting mode disconnects the fourth coil section with the third coil section.

17. The semiconductor structure according to claim 16, wherein the semiconductor structure provides a first inductance in a case where the first route switching circuit operates in the first mode and the second route switching circuit operates in the disconnecting mode;
wherein the semiconductor structure provides a second inductance in a case where the first route switching operates in the second mode and the second route switching circuit operates in the first mode, wherein the second inductance is higher than the first inductance.

18. The semiconductor structure according to claim 17, further comprising:
a fifth coil section, coupled to the second route switching circuit;
a sixth coil section, coupled to the second route switching circuit;
a seventh coil section;
an eighth coil section;
a reference coil section;
a third route switching circuit, coupled to the fifth coil section, the sixth coil section, the seventh coil section, and the eighth coil section, wherein the third route switching circuit operates in the first mode or the second mode, wherein the third route switching circuit in the first mode conducts the fifth coil section with the sixth coil section, and the third route switching circuit in the second mode conducts the fifth coil section with the eighth coil section and conducts the seventh coil section with the sixth coil section;
a fourth route switching circuit, coupled to the seventh coil section, the eighth coil section, and the reference coil section, wherein the fourth route switching circuit operates in the first mode or the second mode, wherein the fourth route switching circuit in the first mode conducts the seventh coil section with the eighth coil section, and the fourth route switching circuit in the second mode conducts the eighth coil section with the reference coil section and conducts the reference coil section with the seventh coil section.

19. The semiconductor structure according to claim 18, wherein the semiconductor structure provides a third inductance in a case where the first route switching circuit operates in the second mode, the second route switching circuit operates in the second mode, and the third route switching circuit operates in the first mode, wherein the third inductance is higher than the second inductance;
wherein the semiconductor structure provides a fourth inductance in a case where each of the first route switching circuit operates in the second mode, the second route switching circuit operates in the second mode, the third route switching circuit operates in the second mode, and the fourth route switching circuit operates in the first mode, wherein the fourth inductance is higher than the third inductance;
wherein the semiconductor structure provides a fifth inductance in a case where the first route switching circuit operates in the second mode, the second route switching circuit operates in the second mode, the third route switching circuit operates in the second mode, and the fourth route switching circuit operates in the second mode, wherein the fifth inductance is higher than the fourth inductance.

20. A method for controlling a semiconductor structure, comprising:
feeding an input signal to a first coil section of the semiconductor structure;
setting a first route switching circuit of the semiconductor structure to operate in a first mode or a second mode in response to a target inductance, wherein the first route switching circuit in the first mode conducts the first coil section with a second coil section of the semiconductor structure, and the first route switching circuit in the second mode conducts the first coil section with a fourth coil section of the semiconductor structure and conducts a third coil section of the semiconductor structure with the second coil section of the semiconductor structure;
setting a second route switching circuit of the semiconductor structure to conduct the fourth coil section of the semiconductor structure with the third coil section of the semiconductor structure; and
receiving an output signal from the second coil section of the semiconductor structure.
